(19) United States
(12) Patent Application Publication
(10) Pub. No.: US 2006/0118806 A1
(43) Pub. Date: Jun. 8, 2006

(54) LIGHT EMITTING DIODE PACKAGE

(76) Inventors: Shyi-Ming Pan, Changhua County (TW); Tsung-Chieh Lin, Taipei County (TW); Fen-Ren Chien, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,192

(22) Filed: Mar. 24, 2005

(30) Foreign Application Priority Data
Dec. 2, 2004 (TW) 93137153

(51) Int. Cl. H01L 33/00

(52) U.S. Cl. 257/99

(57) ABSTRACT

A light emitting diode (LED) package including a chip carrier, an adhesive layer, a light emitting diode (LED) chip and an anti-aging layer is provided. The adhesive is disposed on the chip carrier. The LED chip having a light emitting layer is adhered on the chip carrier by the adhesive layer, and is electrically connected with the chip carrier. The anti-aging layer is disposed between the adhesive and the chip carrier. In the LED package described above, the light emitted from the LED being illuminated on the adhesive layer is reduced or prevented by the anti-aging layer. Therefore, the aging phenomenon of the LED package is retarded, and the lifetime of the LED package is further enhanced.

### CROSS-REFERENCE TO RELATED APPLICATION

This application claims the priority benefit of Taiwan application serial no. 93137153, filed on Dec. 2, 2004.

### BACKGROUND OF THE INVENTION

1. Field of Invention

The present invention relates to a package structure of light emitting diode (LED). More particularly, the present invention relates to an LED package structure with an anti-aging layer.

2. Description of Related Art

In recent years, since the light emitting efficiency of LED is continuously increasing, the application of LED in some field has gradually replaced the usual light bubble or fluorescent light, such as the scanning light source with need of highly reaction speed, the back light source for the LCD (liquid crystal display), the front light source in car for the monitoring panel, the traffic light, or the usual illumination light source. The usual LED is also a semiconductor device, wherein the material in use usually includes the III-V group elements, such as GaP and GaAs. The mechanism for emitting the light in the LED is transforming the electric energy into the light. In other words, by applying a current through the foregoing semiconductor compound material, due to the recombination of electrons and holes, the energy is released by the energy form of light, so that the light emitting effect can be achieved. Since the light emitting phenomenon of LED is not by thermal mechanism or discharging mechanism, it is called electrolumnescent (EL) light, and the lifetime of LED can last for more than hundred thousand hours without idling time. In addition, the LED has advantages of fast response speed (about 10-9 seconds), small volume, low power consumption, low contamination, high reliability, suitable for massive production, so that the applications of LED is very wide.

FIG. 1 is a cross-section view, schematically illustrating a conventional packaging structure of LED. In FIG. 1, the conventional LED structure 100 includes a lead frame structure 102, an adhesive layer 104, an LED chip 106, two bonding wires 108a and 108b, and a packaging structure body 110. Wherein, the lead frame structure 102 has two conductive leads 102a, 102b, and a chip seat 102c disposed on the conductive lead 102a. The adhesive layer 104 is disposed on the chips pad 102c at the conductive lead 102a. The LED chip 106 is adhered to the chips pad 102c via the adhesive layer 104, and the bonding wires 108a, 108b are respectively electrically coupled to the conductive leads 102a, 102b.

FIG. 2 is a perspective view, schematically illustrating the LED structure in use. In FIG. 2, the conventional LED chip 106 is formed from a substrate 106a, an N-type semiconductor layer 106b, a light emitting layer 106c, a P-type semiconductor layer 106d, an N-type contact pad 106e, and a P-type contact pad 106f. Wherein, the N-type semiconductor layer 106b is formed on the substrate 106a, the light emitting layer 106c is formed on the N-type semiconductor layer 106b, and the P-type semiconductor layer 106d is formed on the light emitting layer 106c. In addition, a portion of the N-type semiconductor layer 106b is not covered by the light emitting layer 106c and the P-type semiconductor layer 106d.

In FIG. 1 and FIG. 2, the foregoing N-type contact pad 106e is disposed on the exposed portion of the N-type semiconductor layer 106b, not being covered by the light emitting layer 106c and the P-type semiconductor layer 106d. The P-type contact pad 106f is disposed on the P-type semiconductor layer 106d. Usually, a well ohmic contact is formed between the N-type contact pad 106e and the N-type semiconductor layer 106b, and another well ohmic contact is also formed between the P-type contact pad 106f and the P-type semiconductor layer 106d. In other words, the bonding wires 108a is electrically coupled to the N-type semiconductor layer 106b via the N-type contact pad 106e, and the bonding wires 108b is electrically coupled to the P-type semiconductor layer 106d via the P-type contact pad 106f.

It should be noted in the conventional LED packaging structure that the adhesive layer 104 usually is the silver paste. However, after the silver paste is illuminated by the light which is emitted from light emitting layer 106c, the silver paste is easily aging, causing a poor adhesive capability, and further causing the lifetime of the LED packaging structure to be largely reduced.

### SUMMARY OF THE INVENTION

The invention provides an LED packaging structure with anti-aging layer, so that the aging speed of the LED packaging structure is effectively reduced.

The invention provides an LED packaging structure, including chip carrier, an adhesive layer, an LED chip, and an anti-aging layer. The adhesive layer is disposed on the chip carrier. The LED chip is adhered to the chips carrier by the adhesive layer, and is electrically coupled with chip carrier. In addition, the LED chip has a light emitting layer to emit a light. The anti-aging layer is disposed between the adhesive layer and the light emitting layer.

In an embodiment of the invention, the chip carrier includes a lead frame structure or a circuit board. In the foregoing descriptions, the lead frame structure can include several conductive leads and a chip pad. The chip seat is disposed on one of the conductive leads for holding the LED chip.

In an embodiment of the invention, the adhesive layer includes, for example, silver paste or other adhesive material with good adhesive capability and thermal conductivity.

In an embodiment of the invention, the LED chip includes, for example, a substrate, a patterned semiconductor layer, and two contact pads. The substrate has a first surface and a second surface, and the patterned semiconductor layer is disposed over the first surface, and the contact pads are disposed on the patterned semiconductor layer.

In an embodiment of the invention, the anti-aging layer is, for example, disposed over the second surface. In other words, the anti-aging layer and the patterned semiconductor layer can also be for example respectively disposed on the two opposite surfaces of the substrate. As known by the ordinary skilled artisans, the anti-aging layer can also be disposed between the substrate and the patterned semiconductor layer. In addition, material for the anti-aging layer can be metal, semiconductor, oxide, or polymer.

In an embodiment of the invention, the anti-aging layer can be, for example, an optical absorption layer, a light guiding structure, a filtering layer, or a combination of these layers, so as to reducing the aging effect of the adhesive layer. In addition, the light guiding structure includes, for example, a light guiding layer and a reflection layer, wherein the reflection layer is disposed between the light guiding layer and the adhesive layer.

In an embodiment of the invention, the LED packaging structure further includes a packaging structure body. The packaging structure body is, for example, enclosing the adhesive layer, the LED chip, the anti-aging layer, and a portion of the chip carrier.

In an embodiment of the invention, the LED packaging structure further includes several bonding wires. The bonding wires are connected between the LED chip and the chip carrier.

In the LED packaging structure, since the anti-aging layer, such as optical absorption layer, light guiding structure, or filtering layer, is used in design, the aging of the LED packaging structure can be effectively retarded, and the lifetime of the LED packaging structure can be prolonged.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-section view, schematically illustrating a conventional packaging structure of LED.

FIG. 2 is a perspective view, schematically illustrating the LED structure in use.

FIG. 3 is a cross-section view, schematically illustrating a packaging structure of LED, according to a first preferred embodiment of the invention.

FIG. 4 is a perspective view, schematically illustrating the LED chip in FIG. 3.

FIG. 5 is a cross-sectional view, schematically illustrating the anti-aging layer in FIG. 3.

FIG. 6 is a cross-section view, schematically illustrating a packaging structure of LED, according to a second preferred embodiment of the invention.

FIG. 7 is a perspective view, schematically illustrating the LED chip in FIG. 6.

FIG. 8A and FIG. 8B are perspective views, schematically illustrating a packaging structure of LED, according to a third preferred embodiment of the invention.

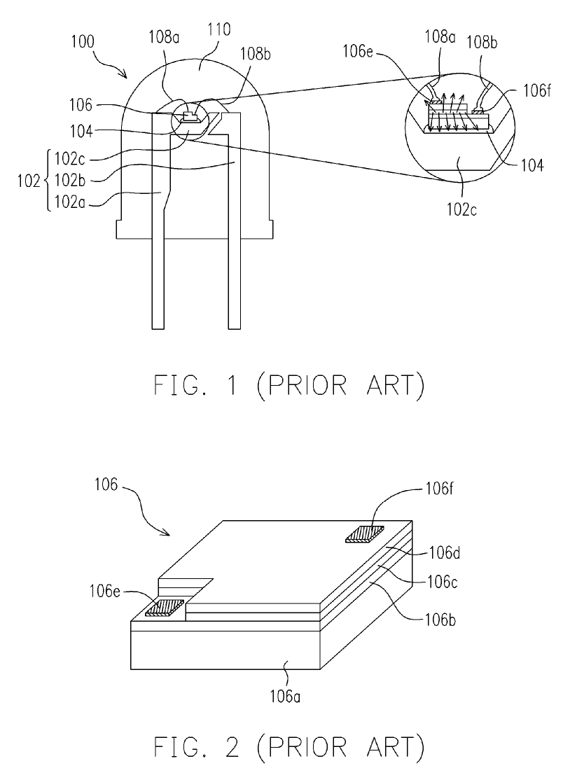

### DESCRIPTION OF THE PREFERRED EMBODIMENTS

### Firs Embodiment

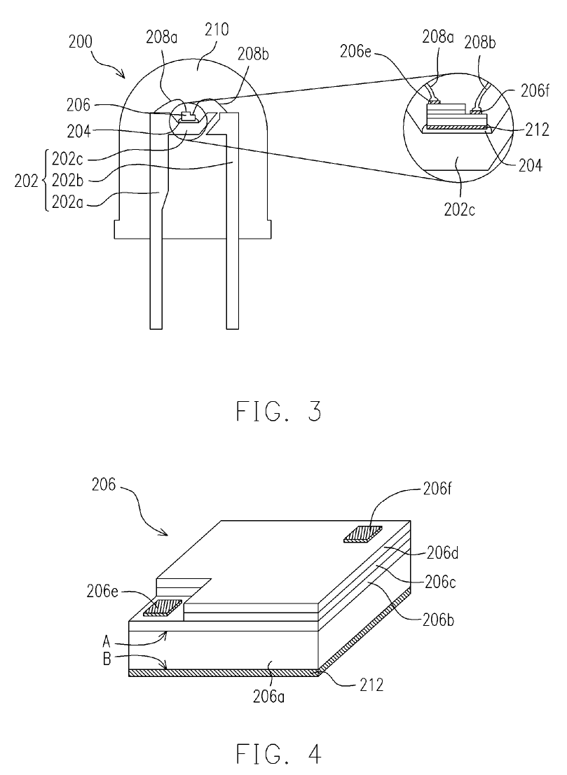

FIG. 3 is a cross-section view, schematically illustrating a packaging structure of LED, according to a preferred embodiment of the invention. In FIG. 3, the LED packaging structure 200 of the embodiment includes a chip carrier 202, an adhesive layer 204, an LED chip 206 and an anti-aging layer 212. Wherein, the adhesive layer 204 is disposed over the chip carrier 202. The LED chip 206 is adhered to the chip carrier 202 by the adhesive layer 204, and is electrically coupled with the chip carrier 202. In addition, the LED chip 206 has a light emitting layer 206c to emit a light. The anti-aging layer 212 is disposed between the adhesive layer 204 and the light emitting layer 206c, so as to prevent the light emitted from the light emitting layer 206c from illuminating on the adhesive layer 204.

In accordance with the foregoing descriptions, the LED packaging structure 200 further includes, for example, the bonding wire 208a and the bonding wire 208b. The bonding wire 208a and the bonding wire 208b are for example coupled between the LED chip 206 and the chip carrier 202. In addition, the LED packaging structure 200 further includes a packaging structure body 210. This packaging structure body 210 can for example enclose the forgoing adhesive layer 204, the LED chip 206, the anti-aging layer 212 and a portion of the chip carrier 202.

The forgoing structures are described in more detail as follows. However, the descriptions are just the examples for descriptions, and the invention is not only limited to the descriptions. The ordinary skilled artisans can base on the descriptions of the invention to have the proper modification without beyond the scope of the invention.

The chip carrier 202 used in the embodiment is for example a lead structure, which includes a conductive lead 202a, a conductive lead 202b, and a chip seat 202c. Wherein, the chip seat 202c is implemented on the conductive lead 202a for holding the LED chip 206.

In order to allow the LED chip 206 to be easily adhered to the chip seat 202c, the foregoing adhesive layer 204 usually needs the good properties of adhesive capability and thermal conductivity. In the embodiment, the adhesive layer 204 can be for example the silver paste or other material with good adhesive capability and thermal conductivity.

FIG. 4 is a perspective view, schematically illustrating the LED chip in FIG. 3. In FIG. 3 and FIG. 4, the LED chip 206 used in the embodiment includes for example a substrate 206a, an N-type semiconductor layer 206b, a light emitting layer 206c, a P-type semiconductor layer 206d, an N-type contact pad 206e, and a P-type contact pad 206f. Wherein, the substrate 206a has a first surface A and a second surface B. The N-type semiconductor layer 206b is formed over the first surface A of the substrate 206a, and the light emitting layer 206c is formed over the N-type semiconductor layer 206b. The P-type semiconductor layer 206d is formed over the light emitting layer 206c. In addition, a portion of the N-type semiconductor layer 206b is not covered by the light emitting layer 206c and the P-type semiconductor layer 206d. As described above, the N-type semiconductor layer 206b, the light emitting layer 206c, and the P-type semiconductor layer 206d are generally called together as a patterned semiconductor layer.

In FIG. 3 and FIG. 4, it can be clearly seen that the N-type contact pad 206e is located on the exposed portion of the N-type semiconductor layer 206b without being covered by the light emitting layer 206c, and the P-type semiconductor layer 206d. In the embodiment, a well ohmic contact can be formed between the N-type contact pad 206e and the N-type semiconductor layer 206b, and another well ohmic contact is also formed between the P-type contact pad 206f and the P-type semiconductor layer 206d.

It can be seen from FIG. 3 and FIG. 4 that the bonding wire 208a is electrically coupled to the N-type semiconductor layer 206b by the N-type contact pad 206e, and the bonding wire 208b is electrically coupled to the P-type semiconductor layer 206d by the N-type contact pad 206f. In the embodiment, the bonding wires 208a, 208b can be for example the gold wire with good tractility.

Accordingly, since the adhesive capability of the adhesive layer 204 becomes worse after being illuminated by the light, it needs the anti-aging layer 212 to be disposed between the light emitting layer 206c and the adhesive layer 204 in the LED chip 206. As a result, the light is effectively blocked and does not illuminate on the adhesive layer 204. In FIG. 4, the anti-aging layer 212 of the embodiment is disposed on the second surface B of the substrate, so as to prevent the adhesive layer 204 from being directly illuminated by the light emitted from the light emitting layer 206c and causing the poor quality. In other words, the anti-aging layer 212 and the patterned semiconductor layer, which includes the N-type semiconductor layer 206b, the light emitting layer 206c, and the P-type semiconductor layer 206d, are respectively disposed on the opposite surfaces of the substrate 206a.

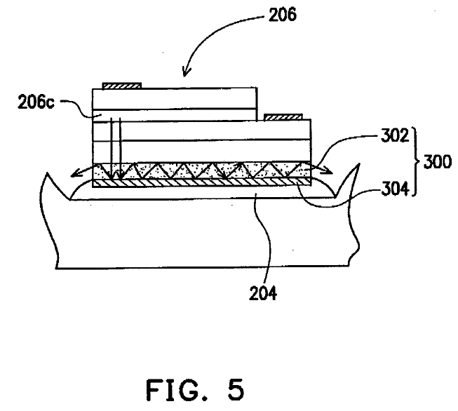

In order to prevent the aging of the adhesive layer 204, the embodiment proposes several designs of the anti-aging layer 212, such as an optical absorption layer, a light guiding structure, a filtering layer, or a combination of these layers. The aging effect is reduced by absorbing, guiding or filtering the light. In more detail, the optical absorption layer used in the embodiment can be, for example, the material of metal or polymer. The ordinary skilled artisans can change the material according to the different wavelength of the emitting light. The light guiding structure used in the embodiment can, for example, guide the light emitted from the light emitting layer 206c to the side of the LED chip 206, so that the light illuminating onto the adhesive layer 204 is greatly reduced. The filtering layer used in the embodiment can be, for example, a stacked structure by multiple films with different refractive index, and can filter the light from the light emitting layer 206c, so as to prevent the adhesive layer 2054 form getting worse. Accordingly, the embodiment takes the light guiding structure as the example for descriptions, as shown in FIG. 5.

FIG. 5 is a cross-sectional view, schematically illustrating the anti-aging layer in FIG. 3. In FIG. 5, the light guiding structure 300 includes for example a light guiding layer 302 and a reflection layer 304. The reflection layer 304 is disposed between light guiding layer 302 and the adhesive layer 204. When the light emitted from the emitting layer 206c of the LED chip 206 is illuminating on the light guiding structure, that is, the anti-aging layer 300, the light is reflected by the reflection layer 304. Wherein, a portion of the light being reflected by the reflection layer 304 emits out from the front surface of the LED chip 206, and the other portion of the light can be guided to the side of the LED chip 206.

Accordingly, the light guiding structure 300 with both capabilities of reflecting the light and guiding the light can effectively prevent the light from directly illuminating on the adhesive layer 204, so that the lifetime and the reliability of the LED package can be effectively improved.

### Second Embodiment

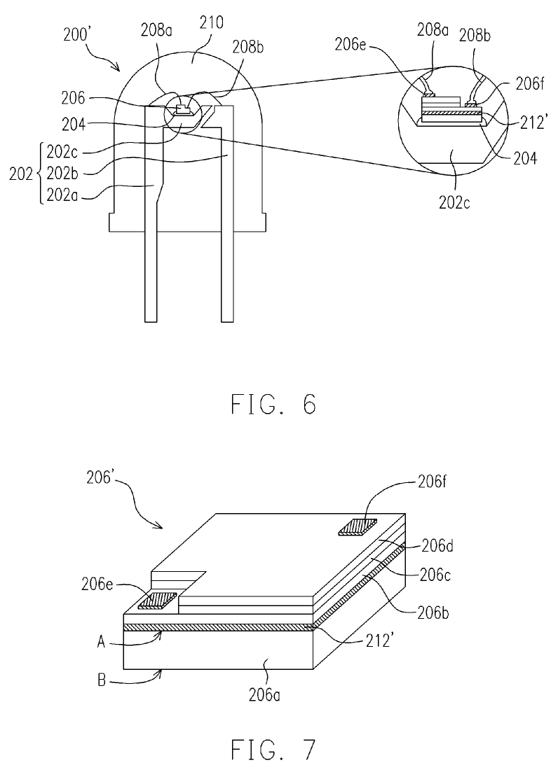

FIG. 6 is a cross-section view, schematically illustrating a packaging structure of LED, according to a second preferred embodiment of the invention. FIG. 7 is a perspective view, schematically illustrating the LED chip in FIG. 6. In FIG. 6 and FIG. 7, the LED packaging structure 200′ of this embodiment is similar to the LED packaging structure 200 of the first embodiment. The difference is that the anti-aging layer 212′ is disposed on the first surface A of the substrate 206 in the LED packaging structure 200′ of this embodiment. This also means that the anti-aging layer 212′ is disposed between the substrate 206a and the N-type semiconductor layer 206b.

### Third Embodiment

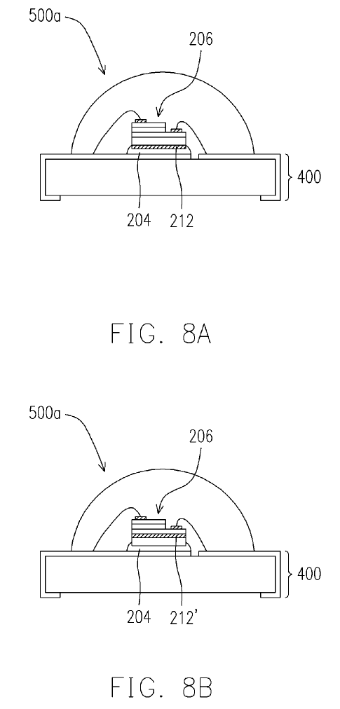

FIG. 8A and FIG. 8B are perspective views, schematically illustrating a packaging structure of LED, according to a third preferred embodiment of the invention. Referring to FIG. 8A, in the LED packaging structure 500a of this embodiment, the LED chip 206 (see FIG. 4) is disposed on a circuit board 400, and the LED chip 206 is adhered to the circuit board 400 by the adhesive layer 204.

Referring to FIG. 8B, in the LED packaging structure 500b of this embodiment, the LED chip 206′ (see FIG. 7) is disposed on a circuit board 400, and the LED chip 206′ is adhered to the circuit board 400 by the adhesive layer 204. In the foregoing packaging structures, the anti-aging layers 212 and 212′ disposed between the adhesive layer 204 and the light emitting layer 206c can effectively prevent the light emitted by the light emitting layer 206c from directly illuminating on the adhesive layer 204, so as to improve the lifetime and the reliability of the LED packaging structures 500a and 500b.

In summary, the LED packaging structures of the invention at least has the advantages as follows.

The LED packaging structures of the invention can effectively retard the aging speed of the LED packaging structures, and further improve the lifetime and the reliability of the LED packaging structures.

The LED packaging structures of the invention can be easily integrated into the current fabrication process without causing much additional fabrication cost.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A light emitting diode (LED) packaging structure, comprising:
a chip carrier;
an adhesive layer, disposed over the chip carrier;
an LED chip, adhered over the chip carrier by the adhesive layer, and electrically coupled with the chip carrier, wherein the LED chip has a light emitting layer to emit a light; and
an anti-aging layer, disposed between the adhesive layer and the light emitting layer.

2. The LED packaging structure of claim 1, wherein the chip carrier comprises a lead frame structure or a circuit board.

3. The LED packaging structure of claim 2, wherein the lead frame structure comprises:
a plurality of conductive leads; and
a chip seat, disposed on one of the conductive leads, for holding the LED chip.

4. The LED packaging structure of claim 1, wherein the adhesive layer comprises silver paste.

5. The LED packaging structure of claim 1, wherein the LED chip comprises:
a substrate, having a first surface and a second surface;
a patterned semiconductor layer, disposed over the first surface of the substrate; and
two contact pads, disposed on the patterned semiconductor layer.

6. The LED packaging structure of claim 5, wherein the anti-aging layer is disposed on the second surface of the substrate.

7. The LED packaging structure of claim 5, wherein the anti-aging layer is disposed between the substrate and the patterned semiconductor layer.

8. The LED packaging structure of claim 1, wherein the anti-aging layer comprises a material of metal, semiconductor, oxide, or polymer.

9. (canceled)

10. The LED packaging structure of claim 1, wherein the anti-aging layer comprises a light guiding structure, for guiding the light emitted from the light emitting layer to an outer region other than the adhesive layer.

11. The LED packaging structure of claim 10, wherein the light guiding structure comprise:
a light guiding layer; and
a reflection layer, disposed between the light guiding layer and the adhesive layer.

12. The LED packaging structure of claim 1, wherein the anti-aging layer comprises an optical filtering layer, for filtering the light emitted from the light emitting layer.

13. The LED packaging structure of claim 1, further comprising a packaging structure body, enclosing the adhesive layer, the LED chip, the anti-aging layer, and a portion of the chip carrier.

14. The LED packaging structure of claim 1, further comprising a plurality of bonding wires, coupled between the LED chip and the chip carrier.

15. A light emitting diode (LED) packaging structure, comprising:
a chip carrier;
an adhesive layer, disposed over the chip carrier;
an LED chip, adhered over the chip carrier by the adhesive layer, and electrically coupled with the chip carrier, wherein the LED chip has a light emitting layer to emit a light; and
an anti-aging layer, disposed between the adhesive layer and the light emitting layer,
wherein the anti-aging layer comprises an optical absorption layer, for absorbing the light emitted from the light emitting layer.
